(19) United States
(12) Patent Application Publication
(10) Pub. No.: US 2026/0162639 A1
(43) Pub. Date: Jun. 11, 2026

(54) SYSTEM AND METHOD OF RETROFITTING A SERVICE RIG WITH SOUND CONTROL

(71) Applicant: Axis Energy Services, LLC, Dallas, TX (US)

(72) Inventors: Eric NEU, Lindsay, TX (US); Joe Ray HALL, Gainesville, TX (US)

(21) Appl. No.: 19/411,650

(22) Filed: Dec. 8, 2025

Related U.S. Application Data
(60) Provisional application No. 63/728,985, filed on Dec. 6, 2024.

(51) Int. Cl. G10K 11/162; E21B 15/00; H05K 7/20

(52) U.S. Cl. CPC G10K 11/162; E21B 15/003; H05K 7/20136

(57) ABSTRACT

A sound reduction system for a rig having a sound producing equipment includes an enclosure at least partially enclosing the sound producing equipment and a sound absorbing material provided on a surface of the enclosure. The rig can be a mobile rig having a chassis, and the sound producing equipment is disposed on the chassis.

### CROSS-REFERENCE TO RELATED APPLICATIONS

This application claims the benefit of priority of U.S. Provisional Patent Application No. 63/728985, filed on Dec. 6, 2024, which application is incorporated herein by reference in its entirety.

### BACKGROUND

### Field

Embodiments of the present disclosure generally relate to rigs, such as drilling or service rigs, and particularly to reducing the sound from rigs.

### Description of the Related Art

Many wellsites need service work performed, such as intervention, stimulation, or abandonment, during its operational life. The wellsites may be located in urban or suburban areas. The wellsites may be constructed, completed, and began production long before any presence of human habitation surrounding the wellsite. Human habitation in these areas can be in the form of commercial buildings or residential homes. Sometimes, new wellsites are constructed, completed and begin production after the human habitation began.

Some wellsites are in a remote location far from any human habitation or development. Though absent of any human habitation, the remote location is inhabited by many different forms of wildlife. Human intervention into these remote areas can affect eco-systems.

Typically, a mobile service rig (also referred to as workover rig) is transported to the wellsite to perform the service work. Often, the service work takes place around the clock, during the day and at night until the work is completed. The traditional service rigs usually include diesel powered generators on or near the service rig to power electrical equipment to perform the service work. Examples of the equipment on or associated with the rig for performing the service work are diesel engines, drawworks, drawworks braking and cooling components, air compressors, winches, swabbing equipment, cooling blowers, hydraulic motors, BOP actuators, pipe or tubular handling equipment, or any auxiliary equipment. These service rigs and all this equipment may produce a lot of sound and unwanted noise that are noticeable and disturbing to the inhabitants of the surrounding environment. In some instances, the noise produced are at levels above what is allowed by laws and ordinances. In some instances, noise levels produced by the equipment make normal speech communication between service workers difficult, resulting in safety or productivity concerns.

There is a need, therefore, for methods and systems for reducing the sound generated from operation of a rig. There is also a need for systems and methods of retrofitting a traditional service rig for sound reduction.

### SUMMARY

The present disclosure generally relates to rigs, such as drilling or service rigs, and particularly to the reduction of sound generated from a rig.

In some embodiments, a sound reduction system for a rig having a sound producing equipment includes an enclosure at least partially enclosing the sound producing equipment and a sound absorbing material provided on a surface of the enclosure.

In some embodiments, a mobile rig includes a chassis and a sound producing equipment disposed on the chassis. The rig also includes an enclosure at least partially enclosing the sound producing equipment and a sound absorbing material provided on a surface of the enclosure.

In some embodiments, a method of reducing sound on a rig having a sound producing equipment includes at least partially enclosing the sound producing equipment in an enclosure, wherein the enclosure includes a sound absorbing material provided on a surface of the enclosure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 illustrates a service rig having a first engine and a second engine.

FIG. 2 is a perspective view of an electric service rig, according to some embodiments.

FIG. 3A is a top view of the service rig of FIG. 2.

FIG. 3B is a side view of the service rig of FIG. 2.

FIG. 4 schematically illustrates a portion of a rig, according to some embodiments.

FIG. 5 is a schematic top view of a sound dampening system at least partially enclosing a motor and an air blower cooler positioned on the service rig, according to some embodiments.

FIG. 6 is a schematic cross-sectional view of the sound dampening system at least partially enclosing the motor and the air blower cooler of FIG. 5, according to some embodiments.

FIG. 7 is a schematic cross-sectional view of another embodiment of a sound dampening system at least partially enclosing the motor and air blower cooler of FIG. 5, according to some embodiments.

FIG. 8A is a schematic cross-sectional view of another embodiment of a sound dampening system at least partially enclosing a liquid cooled motor according to some embodiments.

FIG. 8B is a schematic cross-sectional view of another embodiment of a liquid cooling system for a drawworks motor, according to some embodiments.

FIG. 9 is a schematic top view of a sound dampening system at least partially enclosing a pump and a motor positioned on the service rig, according to some embodiments. The sound dampening system is shown in cross-section.

FIG. 10 is a schematic top view of a sound dampening system at least partially enclosing a hydraulic motor positioned on the service rig, according to some embodiments. The sound dampening system is shown in cross-section.

FIG. 11 is a schematic top view of a sound dampening system at least partially enclosing an air compressor positioned on the service rig, according to some embodiments. The sound dampening system is shown in cross-section.

FIG. 12 is a schematic side view of a sound dampening system at least partially enclosing an air blower cooling system for resistors positioned on the service rig, according to some embodiments. The enclosure of the sound dampening system is shown in cross-section.

FIG. 13 is a schematic side view of a liquid cooling system for resistors positioned on an auxiliary trailer, according to some embodiments.

FIG. 14 is a schematic view of a sound dampening system for use with pipe handling, according to some embodiments.

FIG. 15 is a schematic side view of a sound dampening structure at least partially enclosing repositioned equipment on an auxiliary trailer, according to some embodiments. The enclosure of the sound dampening structure is shown in cross-section.

FIG. 16 is a schematic side view of another sound dampening structure at least partially enclosing repositioned equipment on an auxiliary trailer, according to some embodiments. The enclosure of the sound dampening structure is shown in cross-section.

FIG. 17 is a schematic top view of a service rig and a service trailer located at a well site and how they are typically positioned relative to each other for service work.

FIG. 18 is a graph of sound level readings taken from the blower side of the liquid cooling system of FIG. 8B for a drawworks motor.

FIG. 19 is a graph of sound level readings taken from the front side of the liquid cooling system of FIG. 8B for a drawworks motor.

FIG. 20 is a graph of sound level readings taken from the side opposite the blower side of an alternative liquid cooling system for a drawworks motor of FIG. 8B.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally concerns rigs, such as a drilling rig, a service rig, or a trailer rig, and particularly to the reduction or control sound generated from operation of a rig. In some aspects, the present disclosure relates to the upgrade of a mechanically driven rig to reduce the sound generated from one or more components of the rig. In some embodiments, the rig is a mobile rig.

In some embodiments, an exemplary method of reducing sound generated from a rig includes converting or retrofitting a mechanical engine powered service rig to an all-electric operation service rig. In some embodiments, the sound generated from a rig at 50 ft. is reduced to a level of 75 dB or less.

The present disclosure relates to a sound reduction system and method thereof. In some embodiments, the system includes one or more of electrical power connections to a power company grid, lower sound producing components, or sound reduction devices installed on high sound producing equipment.

In some embodiments, the method includes removing certain high sound producing sources, replacing certain high sound producing sources with lower sound producing sources, or adding sound reduction devices or methods to certain high sound producing sources, wherein the total cumulative sound is reduced when operating of the service rig. The total cumulative sound, also known as the equivalent sound level, is the single value of sound level for any duration which includes all the time-varying sound energy in a measurement period. Since the sound pressure level (amplitude) is measured in dB and therefore logarithmic and not linear, the sound pressure levels of separate sound sources are not directly additive. In some examples, embodiments of the present disclosure decrease the total sound produced by the different sound producing sources of the rig to an equivalent sound level that is no more than 80 dB or no more than 75 dB. In some instances, the equivalent sound level is no more than 62 dB, which is a level that has been established by a study as intrusive to only sporadic complaints.

In some embodiments, a method of reducing the total sound produced by a rig, either separately or in combination, by removing certain high sound producing sources, replacing certain high sound producing sources with lower sound producing sources, or adding sound reduction devices or methods to certain high sound producing sources.

In some embodiments, the systems and methods reduce the total sound produced at a wellsite by a service rig, wherein the cumulative reduction in produced noise is below specified values for intensity and duration, for example, below 75 dB or below 62 dB for urban or suburban areas in a day or a night period.

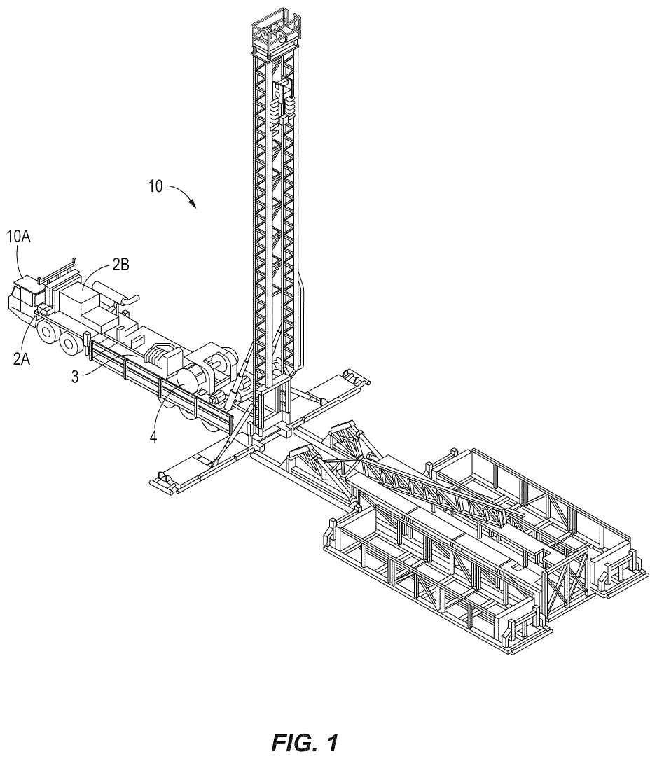

FIG. 1 illustrates a mechanical service rig 10 having a first engine 2A and a second engine 2B. The engines 2A, 2B are typically diesel engines that provide power for transporting the service rig 10 to a wellsite location and mechanically operating all the equipment used to perform the service work. Rig 10 may have a cab 5A where a driver would sit and control the service rig 10 during transport. In one example, the rig 10 may have only one engine 2A for both transporting the rig 1 and for operating mechanically operated equipment used for the service work. In another example, the rig 10 may have two diesel engines 2A, 2B, a first engine 2A for transportation and a second engine 2B for operating the mechanically operated equipment. The mechanically operated equipment used in the operation may be a mechanical transmission 3 and a mechanically powered drawworks 4. The mechanically operated equipment may also include a mechanical brake and at least one winch (not shown).

In the example where the service rig 10 has only one engine 2A, a method of reducing the sound of the service rig 10 includes disconnecting the first engine 2A from any mechanically operated rig equipment, according to some embodiments. After the first engine 2A is disconnected from the mechanically operated equipment, all the mechanically operated equipment is removed from the rig 10. In the example where the service rig 10 has two diesel engines 2A and 2B, the first diesel engine 2A is not removed and only the second engine 2B is disconnected from any mechanically operated equipment used during the service work, according to some embodiments. In some examples, the disconnected engine 2B is removed. The mechanically operated equipment can be removed from the service rig 10 either before or after the second engine 2B is removed. In some examples, equipment removed from the rig 10 includes the derrick and Y-base. The derrick and Y-base are removed and sent to a structural inspection center for API qualification, repair if necessary, and then reinstalled.

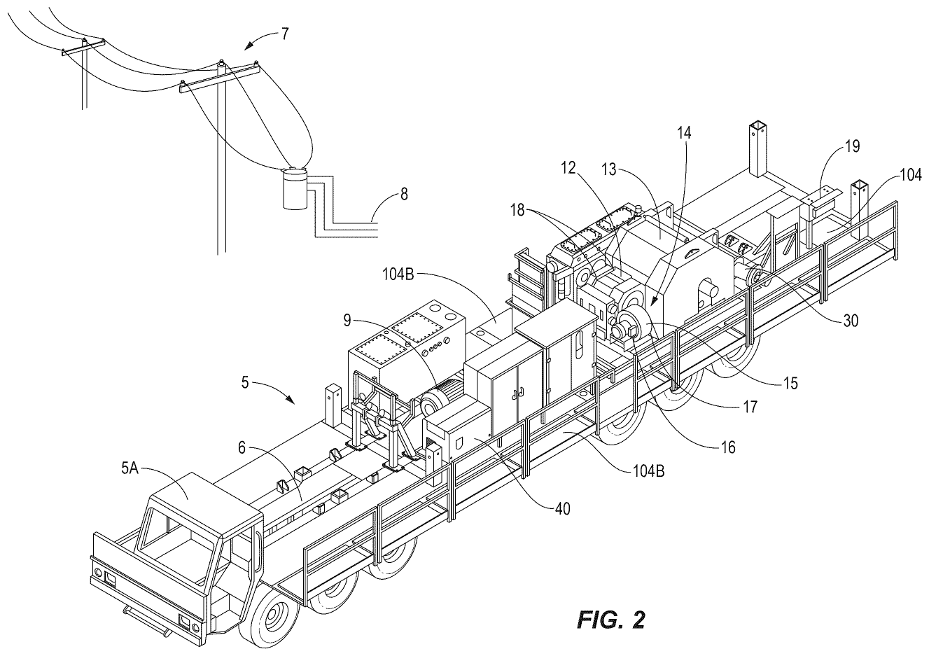

In some embodiments, the service rig 10 may be in the form of a tractor and a trailer. The tractor is used for transporting the trailer rig to the wellsite. If the rig 10 is a trailer rig, the diesel engine used to power the mechanical equipment and any diesel powered mechanical equipment including the derrick and a Y-base are removed. Embodiments disclosed relate to converting or retrofitting a mechanical engine powered service rig to an all-electric operation service rig 5, as shown in FIG. 2.

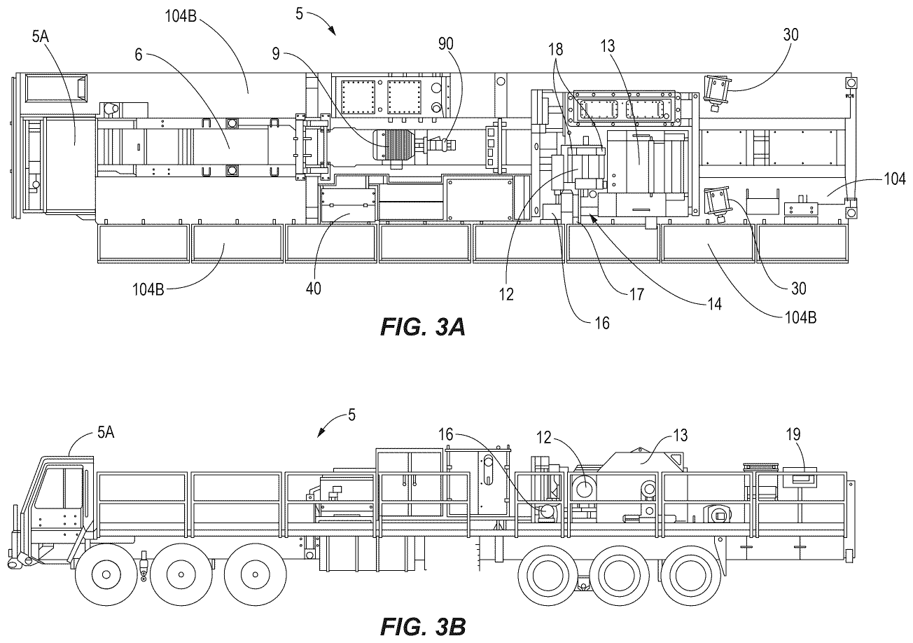

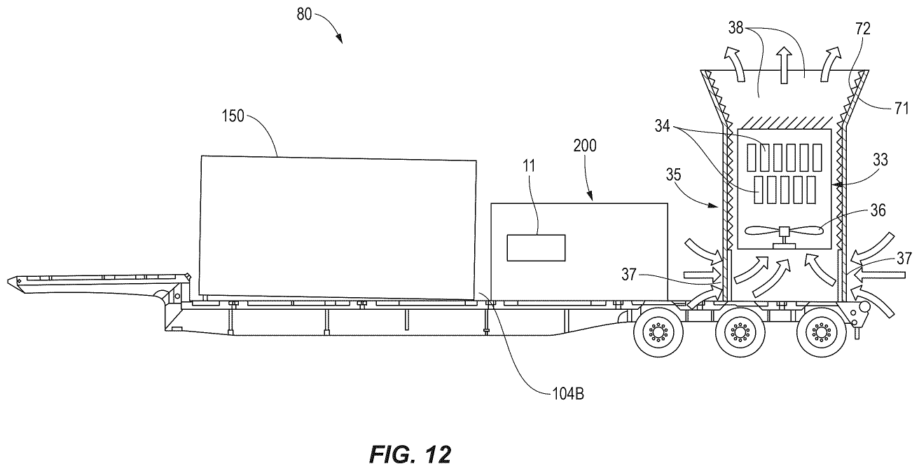

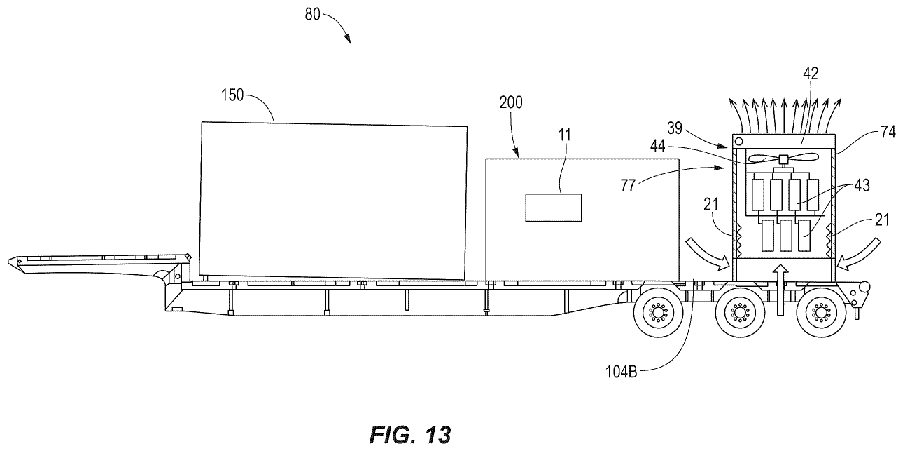

Embodiments disclosed herein relate to systems and methods of reducing the total sound produced by an all-electric service rig 5 at a wellsite by removing or eliminating certain high sound level sources. FIG. 2 is a perspective view of an exemplary embodiment of an electrically operated service rig 5. FIGS. 3A and 3B are a top view and a side view, respectively, of the service rig 5. In this example, electricity for powering the service rig 5 is generated offsite. If the electrical power required to power the all-electric service rig 5 is generated onsite, the engine power generator 150 as shown in FIGS. 12 and 13 may become a source of undesired sound production, e.g., noise. In some embodiments, the engine power generator 150 includes an electricity generation device and a power source, such as a diesel engine or an internal combustion engine. In some embodiments, the engine power generator 150 can be located on the service rig, a trailer rig, or a service trailer. To eliminate this sound-producing source at the wellsite, electrical power generation is produced offsite, i.e., at a location remote from the service rig 5. In one embodiment, connections 8 are provided to connect the service rig 5 to a utility company's power grid system 7, thereby eliminating any onsite power generation. This elimination of the onsite electrical power generation reduces the total sound produced by the rig 5. However, in some embodiments, the service rig 5 includes an onsite power generation equipment, such as a diesel engine, as a secondary or backup electric power source.

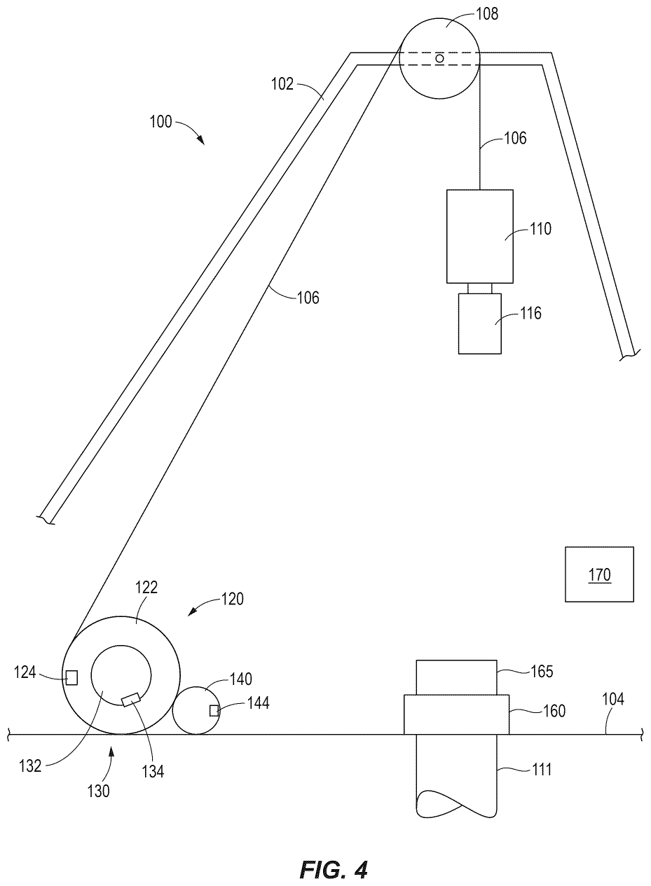

Embodiments of the present disclosure also relate to systems and methods of reducing the total sound output of the service rig 5 by replacing high sound producing equipment with lower sound producing equipment. FIG. 4 schematically illustrates a portion of a rig 100. In some embodiments, the rig 100 is a service rig or forms a part of the service rig, such as service rig 5 shown in FIG. 2. The rig 100 includes a derrick 102 that extends above a floor 104. A crown block 108 is located at an upper end of the derrick 102. A drawworks 120 is located at the floor 104. In some examples, the drawworks 120 is the drawworks 13 of the service rig 5, and the drawworks 120 is located on the service rig 5 instead of the rig floor 104. A traveling block 110 is suspended below the crown block 108 by a cable 106 that extends from the drawworks 120 and around the crown block 108. The traveling block 110 is raised by using the drawworks 120 to retract the cable 106, and is lowered by using the drawworks 120 to pay out the cable 106. In some embodiments, a tubular handling tool 116, such as a top drive, power swivel, or elevator, is suspended from the traveling block 110. In some embodiments, one or more of the tools on the rig 100, such as the tubular handling tool 116, the travelling block 110, or the top drive, are omitted. In some embodiments, the service rig 5 includes a walkway deck 104B for accessing the equipment on the rig 5 or the floor 104.

The drawworks 120 includes a drum 122 and cable 106 wound around the drum 122. Rotation of the drum 122 in one direction retracts the cable 106, and rotation of the drum 122 in an opposite direction pays out the cable 106.

The drum 122 is driven by a motor 140. In some examples, the motor 140 is the drawworks motor 12 of the service rig 5 and may be located on the service rig 5. In some embodiments, the motor 140 is an electric motor. In some examples, the motor 140 is an alternating current (AC) motor. In some examples, the motor 140 is a direct current (DC) motor. The motor 140 is operated to rotate the drum 122 to retract or pay out the cable 106. In some embodiments, the vertical position of the traveling block 110 is deduced from the rotational travel of the drum 122. In some embodiments, the braking of the cable 106 is performed by the electric motor 140. For example, the torque from the electric motor 140 is controlled using a variable frequency drive (VFD) to slow down or stopping the cable 106.

In some embodiments, the drawworks 120 optionally includes a brake 130 coupled to the drum 122. In some embodiments, the brake 130 includes one or more discs 132 and one or more brake shoes 134. The one or more brake shoes 134 bear against the one or more discs 132 to provide a friction braking force to the drum 122. In some embodiments, the one or more brake shoes 134 are biased into contact with the one or more discs 132, such by a spring. The braking force applied to the drum 122 is regulated by applying a release force to the one or more brake shoes 134 that opposes the bias force applied to the one or more brake shoes 134. In an example, the release force is applied by a piston, such as a hydraulic piston.

In some embodiments, the rig 100 includes other one or more equipment, such as winches, mud pumps, and the like.

In some embodiments, a wellhead 160 is located at the rig floor 104 level. The wellhead 160 includes a blowout preventor 165 (BOP) used to isolate the well 111 from the surface. Rams on the BOP 165 are actuated to open the well 111 or close off the well 111. In some examples, the BOP 165 is part of the service rig 5. In some embodiments, the BOP 165 is actuated using a low sound electric motor, hydraulic pump and hydraulic accumulator, instead of compressed gas or diesel engine powered hydraulics. The accumulated pressure then opens and closes the rams hydraulically and reduces the total sound output of the service rig 5.

In some embodiments, the service rig 5 and/or the rig 100 uses electrically operated tongs 170 to make or break tubing joints. In this respect, by replacing hydraulically operated tongs with electrically operated tongs 170, the total sound output of the all-electric rig is reduced.

In some embodiments, the rig 5 is operatively connected to a control system 200 located on a service trailer 80 as shown in FIGS. 12, 13, 15, and 16 for controlling operation of the rig 5 and the associated equipment, such as the motor 12, the drawworks 13, and the BOP 165. In some examples, the control system 200 is located on the service rig 5. The control system 200 includes a controller 11 shown in FIGS. 12, 13, 15, and 16. In some embodiments, the controller 11 includes a central processing unit (CPU), a memory containing instructions, and support circuits for the CPU. The memory, or non-transitory computer readable medium, is one or more of a readily available memory such as random access memory (RAM), read only memory (ROM), floppy disk, hard disk, flash drive, or any other form of digital storage, local or remote. The support circuits are coupled to the CPU for supporting the CPU. The support circuits include cache, power supplies, clock circuits, input/output circuitry and subsystems, and the like. Operations and operating parameters are stored in the memory as a software routine that is executed or invoked to configure the controller 11 into a specific purpose controller to control the operations of the rig 5, 100. The controller 11 is configured to conduct one or more of the operations described herein. The instructions stored on the memory, when executed, cause one or more of the operations described herein to be conducted.

In some embodiments, the all-electric rig 5 uses an electric motor 12 to drive the drawworks 13, which is operatively connected to a geared transmission between the drawworks electric motor 12 and a drum (e.g., drum 122) inside the drawworks 13. The drawworks motor 12 may be a dynamic motor with one or more sensors (e.g., sensor 144), as shown in FIG. 4, on the motor 12 that measure recordable rotation of the motor shaft. The drum may have an encoder and sensors (e.g., sensor 124) that measure recordable rotational movement of the drum shaft as shown in FIG. 4. The drum and the dynamic motor 12 may both have rotational encoders and sensors or multiple encoders and sensors on either the drum or the motor. The cable 106 that typically wraps around the drum operatively connects to the crown block 108 and ultimately the traveling block 110 and/or the hook. An operator inputs commands of raising, lowering, braking, stopping, and holding traveling block 110 and the hook is fed into a command system controller 11 that gives the proper amount power to the motor 12 for an input command. As the drum of the drawworks 13 is rotated by the dynamic motor 12, either letting out cable 106 or wrapping up cable 106, the traveling block 110 is raised and lowered, slowed, stopped and locked in place by the torque-controlled dynamic electrical motor 12. In this manner, use of the electric motor 12 to drive the drawworks 13 reduces the overall sound output of the rig 5, 100.

Rotation, braking, and locking of the drum by the motor 12 uses a lot of precisely controlled torque. The high torque usage of the motor 12 may cause heat to be produced around motor 12 by the electrical power supplied to the motor 12. The electrical fields generated around the coils may produce sufficient heat to impact the operation of the motor 12.

In some embodiments, the rig 5, 100 includes a cooling system 14 for cooling the drawworks electrical motor 12. In some examples, the cooling system 14 includes an air blower 15. In some embodiments, a sound dampening system 20 having a sound absorbing material 21 is used to dampen the sound produced by the cooling system 14, the electrical motor 12, or both, as shown in FIG. 6. The dampening system 20 includes a sound dampening enclosure 61 at least partially enclosing the cooling system 14 and the electrical motor 12 to reduce the sound produced by the cooling system 14. In this example, the air inlet 17 and the air outlet 18 are disposed inside of the sound dampening enclosure 61. In some examples, the enclosure 61 includes one or more enclosure inlets 22 and one or more enclosure outlets 23. As shown, the enclosure inlets 22 extend below the air inlet 17, and the enclosure outlets 23 extend above the air outlets 18. In this example, the enclosure inlets 22 or outlets 23 are oriented in a non-horizontal direction such that the sound waves are not directed horizontally towards the surrounding environment. For example, the enclosure inlets 22 and the outlets 23 are oriented in a vertical direction, e.g., upward and downward. In some examples, the inlets 22 and the outlets 23 are oriented in a vertical direction at an angle from 45 degrees to 135 degrees, from 60 degrees to 120 degrees, or from 75 degrees to 105 degrees, such as 50, 90, or 125 degrees. The enclosure inlets 22 and outlets 23 are configured to allow at least the same or more air flow into and out of the air inlets 17 and outlets 18 as compared to the cooling system 14 without a sound dampening system 20. The interior of the enclosure 61 may include one or more sound absorbing material 21. In some examples, the sound absorbing material 21 may line the interior surface of the enclosure. In some examples, the sound absorbing material 21 has low friction such that the sound absorbing material 21 does not impede the air flow. Exemplary sound absorbing materials include foams made of polyether, polyester, or polyurethane. Other suitable sound absorbing materials include coated fiberglass or faced vinyl panels. By at least partially enclosing the drawworks electric motor 12 and the cooling system 14 with sound absorbing material 21 and directing the enclosure inlet 22 and outlet 23 in a direction that is upward and away from the surrounding environment, embodiments of the cooling system 14 beneficially reduces the total sound produced by the service rig 5, 100.

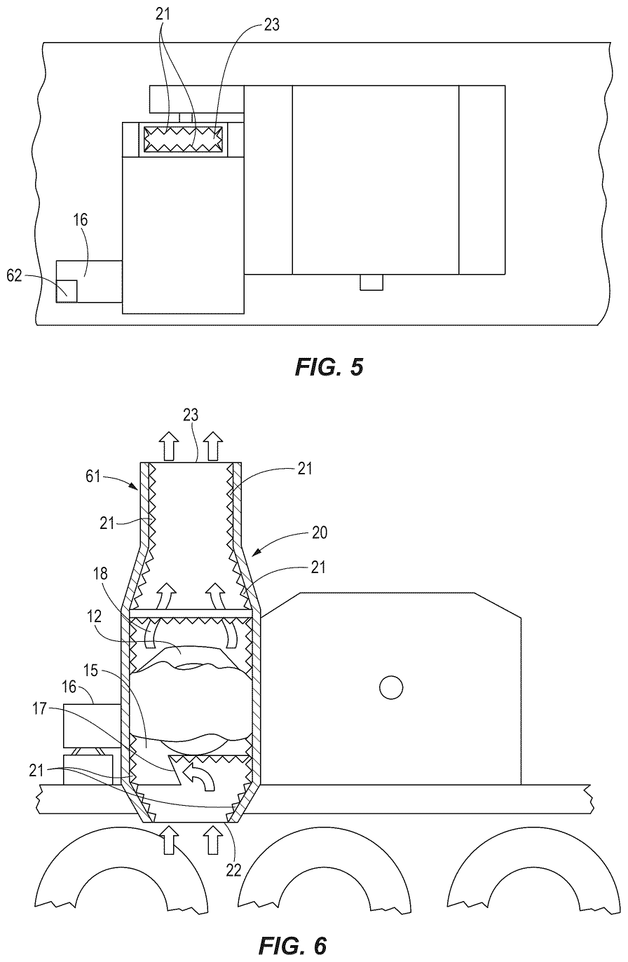

In another embodiment, the blower motor 16 includes a motor speed control system 62 (see FIG. 5) to variably control the rotational speed of the blower motor 16 in addition to turning the blower motor 16 on and off. In this respect, the blower motor 16 and the blower 15 rotational speed may be dynamically controlled by the controller 11 according to cooling needs. In this manner, the blower motor 16 and the blower 15 can be rotated at a slower rate instead of full speed in order to meet a cooling demand. The slower rotational speed of the blower cooling system 14 will produce a lower sound level due to the reduced air flow through the cooling system 14. In some examples, the blower motor 16 may continue operating at the slower rotational speed and only increase to a higher speed if the temperature increases. For example, the blower 15 may run at full speed only when higher cooling is required. It is contemplated the rig 5 may include the variable speed control system 62 in combination with or independent of the sound dampening system 20.

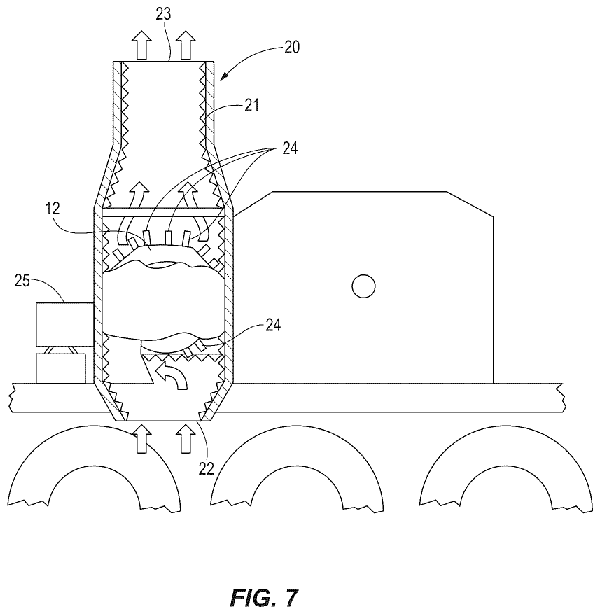

In another embodiment, the electric motor 12 is provided with cooling fins 24 to facilitate cooling of the electric motor 12 of the drawworks 13, as shown in FIG. 7. Heat is conductively transferred from the motor 12 to the fins 24. The heat is then transferred into the air circulating around the fins 24, convectively transferring heat from the fins 24 and into the environment. A heat sink with cooling fins 24 may be used to more efficiently conduct heat away from the motor 12. Because of the increased heat transfer efficiency, a smaller blower motor 25 turning a smaller blower may be used to transfer the heat to the air. The smaller blower motor 25 and/or the smaller blower advantageously produces less sound than the motor 12 and/or the blower 15. In another embodiment, the motor speed control system disclosed above may be used to control the speed of the smaller, quieter blower and/or blower motor 25 circulating air around the heat sink fins 24 on the electric motor 12. Embodiments of the cooling fins 24 on the motor 12 may be used in combination with the sound dampening system 20.

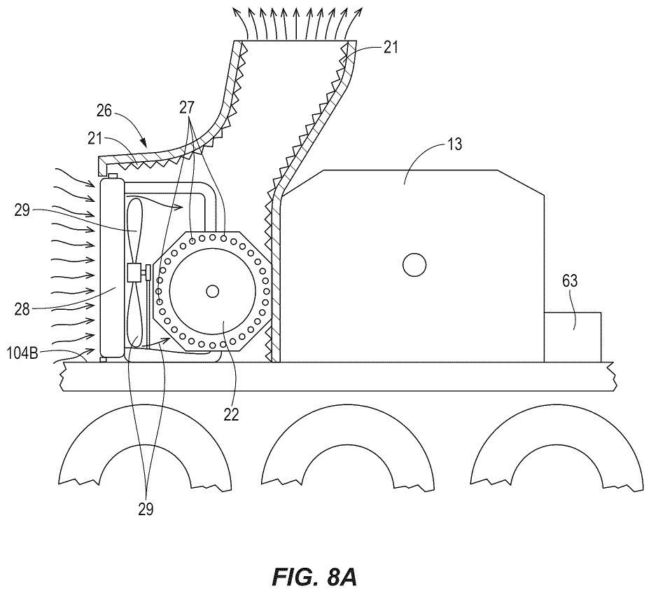

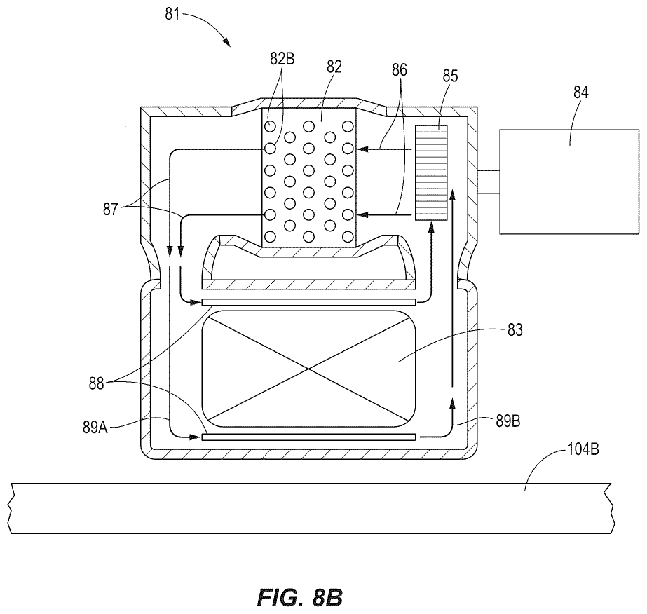

In another embodiment, all-electric service rig 5 includes a liquid cooling system 26, as shown in FIG. 8A, instead of an air cooling system 14 for cooling the drawworks electrical motor 12. In some embodiments, the liquid cooling system 26 includes one or more cooling jackets or cooling tubes 27 coupled to the motor 12. In some embodiments, the liquid cooling system is part of the motor design as supplied from the manufacturer. In some examples, the liquid cooling system 26 may include any suitable liquid heat transfer apparatus thermodynamically coupled to the motor 12. In some embodiments, heat produced by the motor 12 is transferred to the liquid flowing through the transfer apparatus, such as the cooling tubes 27 by a pump 63 or other circulation system into a heat exchanger such as a radiator 28 and into the environment. The radiator 28 may be an internal liquid to ambient air heat transfer system. The radiator 28 may use natural air flow or forced air by a forced air system 29 having a motor and fan. The forced air system 29 on the radiator 28 can be a low noise air circulation system. The liquid cooling system 26 may be used in combination with the sound dampening system 20 to further reduce the overall sound level of the liquid cooling system 26. In some examples, the sound levels produced by the liquid cooling system 26 are lower than the sound levels of the air cooling system. This reduction of sound using a liquid cooling system 26 advantageously lowers the total sound level produced by the rig to an acceptable level. In some examples, the radiator 28 for the liquid cooling system 26 using either natural air flow or using the forced air system 29 may be located next to the electric motor 12. In some examples, the radiator 28 for the liquid cooling system 26 using either natural air flow or using the forced air system 29 may be located remote from the liquid cooled motor 12 at another location of the service rig 5 or on a separate trailer.

In another embodiment, all-electric rig 5 includes an alternative liquid cooling system 81 for cooling the electrical motor 83 (e.g., motor 12) for the drawworks, as shown in FIG. 8B. In this embodiment, the liquid cooling system 81 includes a closed loop air to liquid heat exchanger system functionally coupled to the electrical motor 83. The liquid cooling system 81 transfers heat generated from the motor 83 to air circulating through an air conduit system 88, which may surround the windings of the motor 83. A blower impeller 85 powered by an electric blower motor 84 is used to circulate air around the closed loop system. The air is circulated in a direction shown by arrows 86 to 87 and arrows 89A to 89B. The air flows through the air conduit system 88 in the direction from arrow 89A to 89B. The heat generated by the motor 83 is transferred to the air circulating in the air conduit system 88. After absorbing the heat, air leaving the air conduit system 88 in the direction of arrow 89B flows toward the blower 85. In turn, the blower 85 circulates the air in the direction of arrow 86.

The liquid cooling system 81 may also include an air to liquid heat exchanger 82 disposed downstream of the blower 85. The heat exchanger 82 includes a plurality of heat exchanger tubes 82B and a heat exchange liquid flowing through the plurality of heat exchanger tubes 82B. The heat exchange liquid may be water, ethylene glycol, a water mixture or any suitable heat exchange liquid. The heat exchange liquid inside the heat exchanger tubes 82B is circulated from an inlet to an outlet of the tubes 82B, not shown, by a pump, also not shown. The inlet and the outlet are located on the heat exchanger 82.

Air circulated in the direction of arrow 86 comes into contact with the heat exchanger tubes 82B. The air transfers heat to the heat exchange tubes 82B, which heat passes into the circulating heat exchange liquid. The heat exchange liquid may exit the outlet, and the heat carried by the heat exchange liquid may be dissipated into a tank open to the air or a radiator system, not shown, or any other method of dispersing the heat away from the heat exchange liquid. The cooled heat exchange liquid is re-circulated back into the heat exchanger at the tube inlet. In some embodiments, the heat exchange liquid may circulate in a closed loop system, or the heat exchange liquid may be sourced from a fresh supply and deposited into a drainage system and not re-circulated.

In another embodiment, the liquid cooling system 81 of FIG. 8B may be enclosed or partially enclosed in a sound dampening enclosure 61 with sound absorbing material 21, similar to the embodiments of FIGS. 5 and 6.

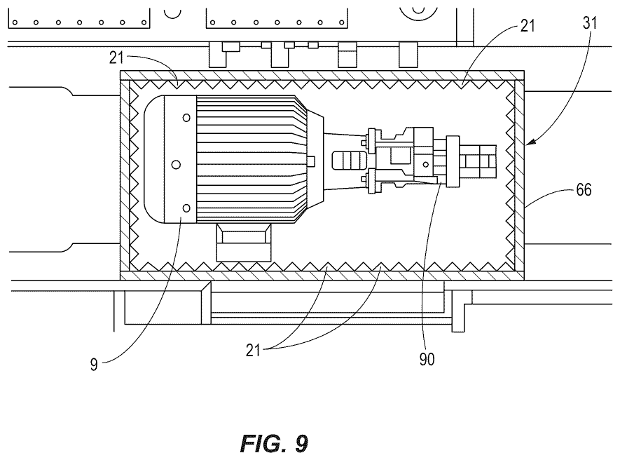

Another source of sound produced by the service rig 5 is a hydraulic pump 9 and corresponding hydraulic motors such as winching motors 30 used on the derrick. In some embodiments, the hydraulic pump motor 9 is driven by electricity from the service rig 5. In one embodiment, the hydraulic pump motor 9 and the hydraulic pump 9 are at least partially enclosed with a sound dampening system 31 to reduce the cumulative sound output of the service rig 5. Referring to FIG. 9, the sound dampening system 31 includes a sound dampening enclosure 66 disposed at least partially around the hydraulic pump motor 9 and the hydraulic pump 90. The sound dampening enclosure 66 is at least partially lined with a sound absorbing material 21, as discussed above.

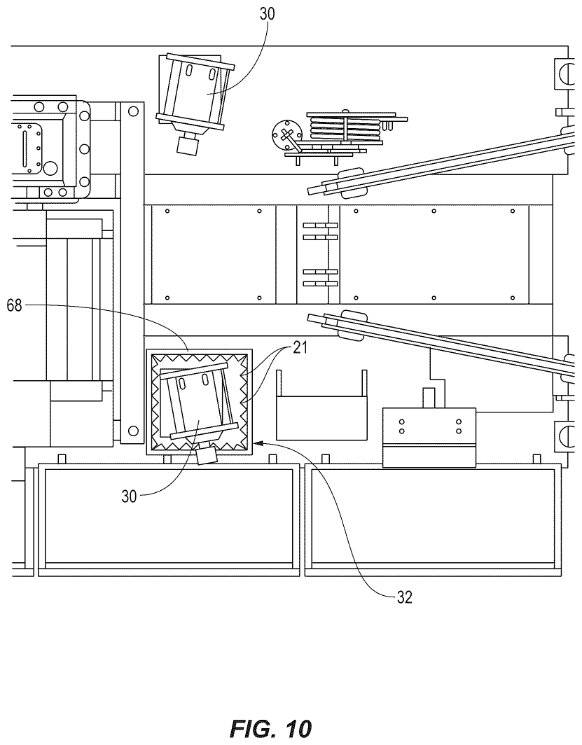

The hydraulic motors operating the winches and swab line and may produce a significant amount of sound into the surrounding environment. Referring to FIG. 10, a sound dampening system 32 having a sound reduction enclosure 68 having sound absorbing material 21 encloses or partially encloses the hydraulic motors 30 used for winches or other hydraulic motors. In this manner, the total sound output of a service rig 5, 100 can be beneficially reduced by enclosing or partially enclosing hydraulic motors 30 with a sound dampening system 32.

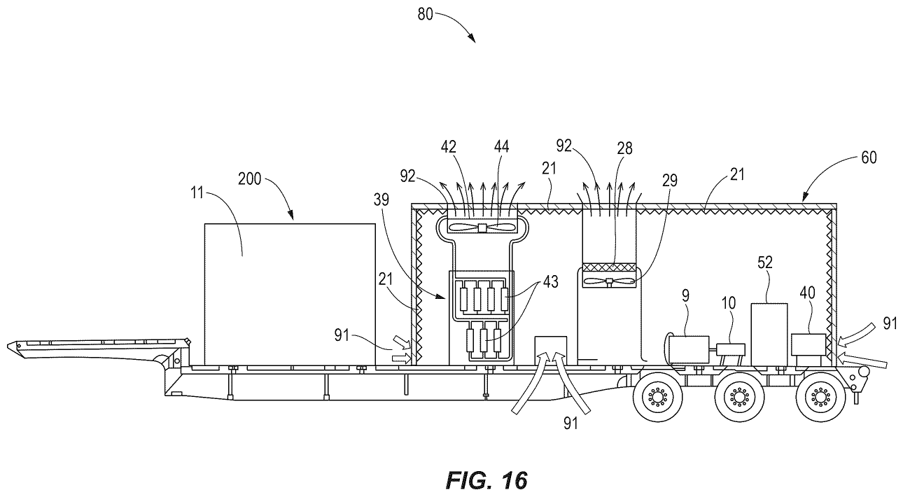

In some embodiments, the all-electric rig 5 includes a second hydraulic pumping system, a brake hydraulic pumping unit (brake HPU) 52 shown in FIG. 16 having a hydraulic pump electric motor and a corresponding hydraulic pump used in the operation of a drawworks mechanical brake. The brake HPU 52 may be located on the all-electric rig 5 or on a separate truck or trailer 80 using appropriate hydraulic hoses and communication between the service rig 5 and trailer 80. In some embodiments, the brake HPU 52 is at least partially enclosed using a sound dampening enclosure 60 equipped with a sound absorbing material 21 to reduce the cumulative sound output of the electric service rig 5.

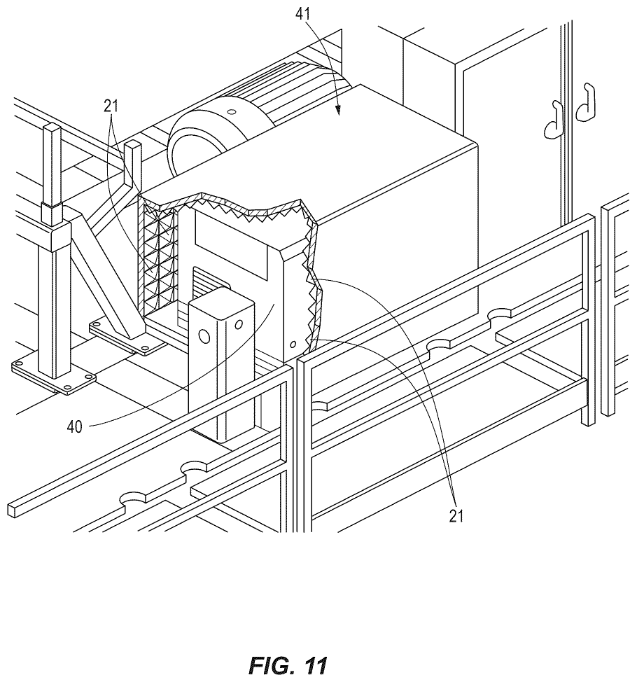

In some embodiments, the service rig 5 includes an air compressor 40 for providing compressed air to operate pneumatic equipment on the rig such as power slips or other pneumatic tools. As shown in FIG. 11, the air compressor 40 may be at least partially enclosed with a sound reduction enclosure 41 having sound absorbing material 21. In some examples, the air compressor 40 has an electric motor and a compression mechanism design such as piston or screw. In some embodiments, the air compressor enclosure 41 may also have an air intake that is directed substantially vertical, e.g., upwards or downwards, and may contain an intake baffling muffler to reduce the sound produce of air entering the compressor 40. In this manner, the air compressor enclosure 41 beneficially reduces the cumulative sound output of the service rig 5, 100.

The electric motor 12 that drives the drawworks 13 may also generate electricity as a generator during braking. The mechanical energy is converted into electrical energy, which is transferred to large resistors 34 that may be located on the service trailer 80. As shown in FIG. 12, the resistor 34 is located on the chassis of the service trailer 80. The resistors 34 generate substantial amounts of heat requiring cooling. An air blower system 33 may be used to cool the resistors 34 which then dissipate the heat into the environment. The blower system 33 uses a blower 36 to circulate air past the resistors 34. The blower 36 may generate unwanted noise during operation. In one embodiment, a sound dampening system 35 is provided to at least partially enclose the cooling blower 36, as shown in FIG. 12. In one example, the dampening system 35 includes an enclosure 71 having a sound absorbing material 72 that surrounds the air blower system 33 including the blower 36. The sound dampening enclosure 71 may have at least one enclosure inlet 37 and at least one enclosure outlet 38. In this example, the enclosure inlet 37 allows air to come into the enclosure 71 from the sides of the enclosure 71, but the enclosure inlet 37 may be oriented vertically. The enclosure outlet 38 may be oriented substantially vertical, e.g., upwards or downwards, directing the sound away in a non-horizontal direction away from the surrounding habitat. In some examples, the enclosure outlet 38 has an enlarged outlet 38 opening to facilitate air flow out of the enclosure 71. In some embodiments, a method of reducing the total sound produced by the service rig 5 includes enclosing or partially enclosing an air blower system 33 with a sound dampening system 35 and directing the inlet 37 and outlet 38 in a direction away from the surrounding environment.

In another embodiment, a sound reduction system and method to reduce the total sound output from a service rig 5, 100 involves cooling the resistors 43 using a liquid cooling system 39 that may be located on the service trailer 80, as shown in FIG. 13. Any suitable liquid cooled resistors 43 which are readily available may be used in the cooling system 39. A radiator 42 using an electric circulation pump (not shown) transfers the heat away from the resistors 43 into the cooling liquid. In turn, the cooling liquid transfers the heat through the radiator 42 and into the air. The radiator 42 may be any suitable liquid to air heat transfer radiator. The external air which convectively transfers the heat into the air may use natural circulation or forced air circulation generated by a forced air system 77 having an electric motor and fan 44. A low noise fan 44 may be used to continually or intermittently circulate air through the radiator 42. The forced air system may use a variable speed motor controlled by the controller 11 to run the motor and fan at a speed sufficient to cool the resistors 43. In some examples, the motor and fan 44 may operate intermittently at a speed sufficient to keep the resistors 43 within a predetermined temperature range instead of running continuously. The forced air system for the radiator 43 may be at least partially enclosed by a sound dampening enclosure 74 having sound absorbing material 21 to further reduce the sound level coming from the cooling system 39.

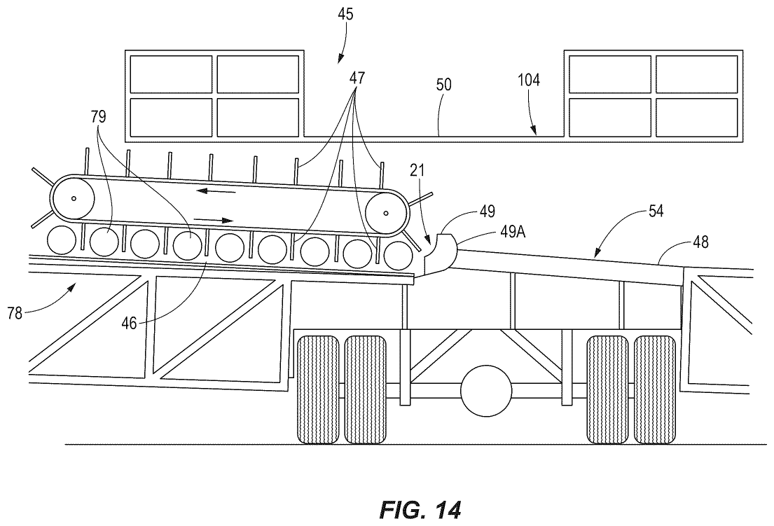

In some embodiments, systems and methods of reducing the cumulative sound produced by the service rig 5, 100 employ a sound dampening system 45 that prevents or reduces each pipe 79 from contacting any hard surface, as shown in FIG. 14. Pipe 79, when moved, may bang against other pipe, against the pipe rack, catwalk, troughs, rig floor near the hole or pipe rack. In some examples, a sound dampening layer 46, such as an elastomer material or the sound absorbing material 21, is disposed on the surface of the pipe rack 78 in contact with the pipe 79. The sound dampening system 45 may optionally include a pipe separation device 47 used to keep the pipes 79 separated and prevent contact with another pipe 79 while on the rack 78. In some embodiments, sound absorbing material 21 is disposed on a surface 49A of trough 49. In some examples, the pipe separation device 47 may be made of a non-metallic material such as an elastomer material or the sound absorbing material 21. In this example, the pipe separation device 47 has an elongated, flat shape that separates two pipes 79. In one or more embodiments disclosed herein, the sound absorbing layer may be applied on the surface in liquid form and allowed cure, or the sound dampening layer may be applied on the surface as a solid layer. In solid layer of sound dampening layer may be applied on the surface using an adhesive.

In some embodiments, a sound dampening layer 48 is disposed on the catwalk 54. The sound dampening layer 48 may be made of an elastomer or the sound absorbing material 21. In some examples, a sound dampening layer 48 is provided on any trough lifting surface 49A of the catwalk 54 that may contact a portion of the pipe 79, such the side or end of the pipe 79. In another embodiment, a rig floor sound dampening layer 50 is disposed on the surface of the rig floor 104 that may contact the bottom end of the pipe 79. Another embodiment of the invention is to apply a sound dampening layer 48 to the pipe racking system of the finger that would contact the pipe 79. Embodiments disclosed herein includes methods of reducing the cumulative sound output of the service rig 5 by retrofitting the service rig 5 with a pipe handling sound dampening system 45 that utilizes a sound absorbing material on one or more surfaces in contact with a pipe 79, such as another pipe 79 or any other hard surface during pipe handling. In some embodiments, the sound dampening system 45 used to handle pipe 79 may also be used to handle any tubular, tool, or equipment lifted on or off the service rig 5. For example, a sound dampening layer 48 may be applied on one or more surfaces of an elevator configured to contact a pipe 79.

In some embodiments, the sound dampening layer 48 is provided on a hard surface to reduce the sound reflected from the hard surface. For example, the sound dampening layer is applied to one or more surfaces of the rig floor, derrick, Y-base, or any hard surface on the rig 5, 100. The sound dampening layer reduces the sounds from the rig that are reflected into the environment surrounding the rig. As discussed above, the sound dampening layer may be applied on the reflective surfaces in liquid form and allowed cure, or the sound dampening layer may be applied on the reflective surfaces as a solid layer.

In some embodiments, a sound dampening structure is provided to at least partially enclose one or more auxiliary equipment that support the service work. Examples of auxiliary equipment may be mud pumps and shakers. The sound dampening structure may be any of the sound dampening enclosure disclosed herein. In some examples, the sound dampening structure is a portable building having sound absorbing material. The sound dampening structure can be positioned on a trailer and surrounds the sound producing auxiliary equipment. In some embodiments, the auxiliary equipment is moved from the trailer to the wellsite ground. A sound dampening structure is built around the auxiliary equipment. The sound dampening structure may be built as a temporary or permanent structure.

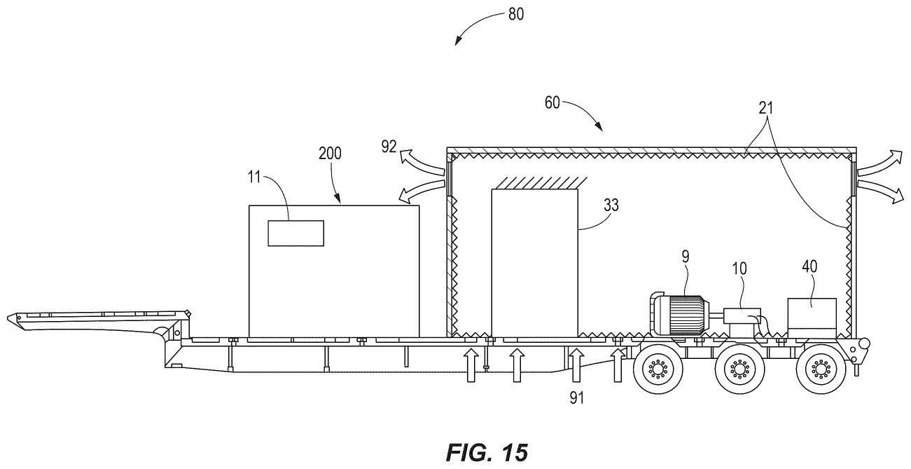

In some embodiments, the service rig 5 may be retrofitted to reduce the total sound output by moving one or more equipment to another location, such as a service trailer 80 or skid, as shown in FIG. 15. The removed equipment are at least partially enclosed in a sound dampening structure 60 to reduce the sound output to the surrounding environment. The one or more equipment may a sound producing equipment, such as the hydraulic pump motor 9, the hydraulic pump 90, the air compressor 40, and the heat dispensing resistors cooling system 33. While this equipment are used to perform the service work, they are not required to be located on the service rig 5, 100, and thus, can be moved to an sound reducing location. In some examples, the sound dampening enclosure 60 includes a sound absorbing material 21 on one or more of its surfaces, either interior or exterior. The sound dampening enclosure 60 may be any suitable sound dampening enclosure disclosed herein. In some examples, a single enclosure 60 is used to enclose the moved equipment. In some examples, electrical lines and/or hydraulic lines are provided to connect the single enclosure with equipment located therein and with the service rig 5, 100 for the service work. In some embodiments, the enclosure 60 includes one or more inlets 91 and one or more outlets 92 to facilitate cooling of the enclosure 60. In some examples, the outlets are configured to direct air substantially away in a non-horizontal direction toward the surrounding environment. In some embodiments, systems and methods of reducing the total sound output of a service rig involves combining one or more of the hydraulic pump, air compressor, resistor cooling blower into a single sound dampening structure 60 and using directional air inlet and air outlet to direct the air substantially upwards.

FIG. 16 illustrates another embodiment of a sound dampening enclosure 60 which houses one or more high sound level pieces of equipment on the service trailer 80. In this example, the sound dampening enclosure 60 additionally includes the brake HPU 52 and the resistors 43. To facilitate cooling of the enclosure 60, the enclosure 60 includes a radiator 28. The radiator 28 may use natural air flow or forced air by a forced air system 29 having a motor and fan to direct air towards the outlet 92. In some embodiments, a cooling system 39, including the radiator 42 and fan 44, for cooling the resistors 43 are also positioned in the enclosure 60.

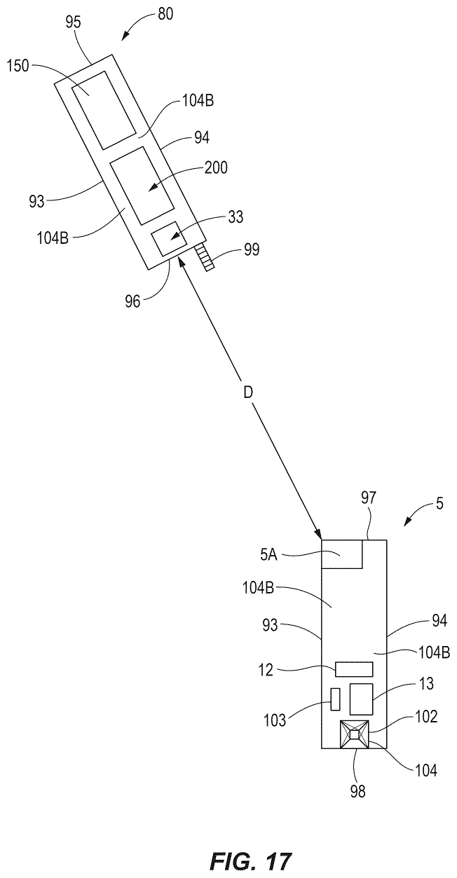

FIG. 17 is a schematic top view of a service rig 5 and a service trailer 80 located at a well site, according to some embodiments. FIG. 17 shows exemplary positions of the service rig 5 relative to the service trailer 80 for service work. The service trailer 80 is shown with the generator 150, the control system 200, and the blower 33. However, the service trailer 80 may include additional equipment as discussed herein. The service trailer 80 has a right side 94, a left side 93, a resistor end 96, and a generator end 95. The stairs 99 of the service trailer 80 is shown at the resistor end 96.

The service rig 5 has a cab 5A located near the cab end 97 and a derrick 102 located on a rig floor 104 near the derrick end 98. The service rig 5 also includes a motor 12, a drawworks 13, and an operator stand 103. The service rig 5 is separated from the service trailer 80 by a distance “D”, which may be from 20 ft. to 1,000 ft., from 25 ft. to 500 ft., from 30 ft. to 200 ft., or any suitable distance.

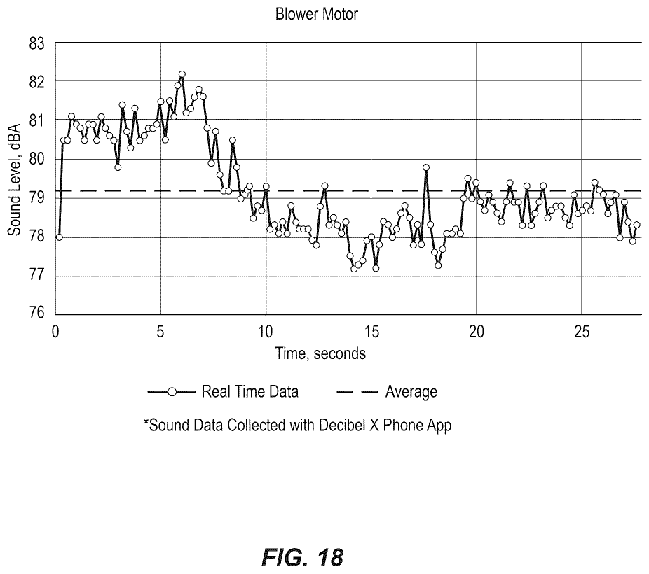

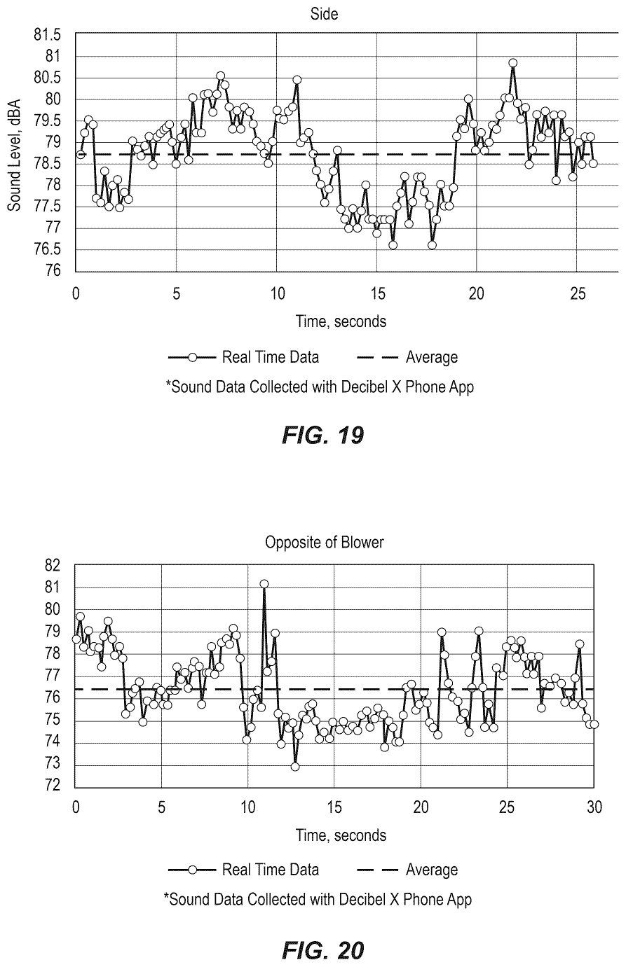

FIGS. 18-20 show the sound levels of the liquid cooling system 81 of FIG. 8B as measured from different locations around the liquid cooling system 81. FIG. 18 shows the sound levels measured at the blower motor 84 in FIG. 8B. FIG. 19 shows the sound levels measured at the side (i.e., from the side looking into the page) of the liquid cooling system 81. FIG. 20 shows the sound levels measured from the opposite side (i.e., from the side where reference number “87” is located in FIG. 8B) of the blower motor 84. The sound level readings are an average of 30 second of samples. The average readings of FIGS. 18-20 ranged from a little over 79 dB to 76 dB depending on the location around the liquid cooling system 81. In comparison, an air cooled system not using a sound dampening enclosure as shown in FIG. 2 has sound level readings in the upper 80 dB to over 90 dB as measured from the right side of the rig floor.

In some embodiments, a sound reduction system for a rig having a sound producing equipment includes an enclosure at least partially enclosing the sound producing equipment and a sound absorbing material provided on a surface of the enclosure.

In some embodiments, a mobile rig includes a chassis and a sound producing equipment disposed on the chassis. The rig also includes an enclosure at least partially enclosing the sound producing equipment and a sound absorbing material provided on a surface of the enclosure.

In some embodiments, a method of reducing sound on a rig having a sound producing equipment includes at least partially enclosing the sound producing equipment in an enclosure, wherein the enclosure includes a sound absorbing material provided on a surface of the enclosure.

In some embodiments, the sound absorbing material comprises a foam material.

In some embodiments, the sound absorbing material is one of polyether, polyester, polyurethane, coated fiberglass or faced vinyl panel.

In some embodiments, the rig is a service rig, a trailer rig, or a service trailer.

In some embodiments, the sound producing equipment is at least one of an electric motor, a hydraulic motor, a hydraulic pump, air compressor, a pipe handling equipment, a radiator motor, a cooling system, or combinations thereof.

In some embodiments, the electric motor operates drawworks equipment.

In some embodiments, the hydraulic motor is configured to operate a winch.

In some embodiments, a sound absorbing layer is provided on a surface of pipe handling equipment.

In some embodiments, the pipe handling equipment is one or more of a pipe rack, a trough, or a catwalk.

In some embodiments, a sound absorbing layer provided on the sound producing equipment.

In some embodiments, the enclosure comprises an inlet and an outlet, wherein at least one of the inlet and the outlet has a non-horizontal orientation.

In some embodiments, at least one of the inlet and the outlet has a vertical orientation.

In some embodiments, the outlet has an enlarged opening.

In some embodiments, a cooling system is provided for cooling one or more sound producing equipment in the enclosure.

In some embodiments, the cooling system comprises an air cooling system having a fan operated by a variable frequency drive.

In some embodiments, the cooling system comprises a liquid cooling system having a radiator.

In some embodiments, a forced air system is provided to supply air to the radiator.

In some embodiments, the liquid cooling system comprises an air to liquid heat exchanger system.

In some embodiments, the cooling system is at least partially disposed in the enclosure.

In some embodiments, the overall sound output of the rig is not more than 80 dB.

In some embodiments, the enclosure encloses at least one of a resistor, a pump unit, or both.

In some embodiments, a cooling system is provided for cooling the resistor.

In some embodiments, the sound producing equipment is connected to an electric source located remotely from the rig.

In some embodiments, the electric source is an electric grid.

In some embodiments, a diesel engine is removed from the rig.

In some embodiments, the sound producing equipment on the rig is replaced with an electric powered equipment.

In some embodiments, the sound producing equipment in the enclosure is cooled using at least one of a liquid cooling system or an air cooling system.

In some embodiments, the air cooling system includes a fan, and the fan is operated using a variable frequency drive.

In some embodiments, air is supplied across the radiator.

In some embodiments, the supplied air is provided by a forced air system having a motor and fan.

In some embodiments, the fan is operated using a variable frequency drive.

In some embodiments, the sound producing equipment is removed from the rig and positioned inside the enclosure.

It is contemplated that any one or more elements or features of any one disclosed embodiment or example may be beneficially incorporated in any one or more other non-mutually exclusive embodiments or examples. While the foregoing is directed to embodiments of the present disclosure, other and further embodiments of the disclosure may be devised without departing from the basic scope thereof, and the scope thereof is determined by the claims that follow.

What is claimed is:

1. A sound reduction system for a rig having a sound producing equipment, comprising:
an enclosure at least partially enclosing the sound producing equipment; and
a sound absorbing material provided on a surface of the enclosure.

2. The sound reduction system of claim 1, wherein the sound absorbing material comprises a foam material.

3. The sound reduction system of claim 1, wherein the sound absorbing material is one of polyether, polyester, polyurethane, coated fiberglass or faced vinyl panel.

4. The sound reduction system of claim 1, wherein the sound producing equipment is at least one of an electric motor, a hydraulic motor, a hydraulic pump, air compressor, or a radiator motor.

5. The sound reduction system of claim 1, wherein the enclosure comprises an inlet and an outlet, wherein at least one of the inlet and the outlet has a non-horizontal orientation.

6. The sound reduction system of claim 1, further comprising a sound absorbing layer provided on the sound producing equipment.

7. A mobile rig, comprising:
a chassis;
a sound producing equipment disposed on the chassis;
an enclosure at least partially enclosing the sound producing equipment; and
a sound absorbing material provided on a surface of the enclosure.

8. The mobile rig of claim 7, wherein the sound absorbing material comprises a foam material.

9. The mobile rig of claim 7, wherein the sound absorbing material is one of polyether, polyester, polyurethane, coated fiberglass or faced vinyl panel.

10. The sound reduction system of claim 7, wherein the rig is a service rig, a trailer rig, or a service trailer.

11. The mobile rig of claim 7, wherein the sound producing equipment is at least one of an electric motor, a hydraulic motor, a hydraulic pump, air compressor, a pipe handling equipment, a radiator motor, a cooling system, or combinations thereof.

12. The mobile rig of claim 7, further comprising a sound absorbing layer provided on a surface of pipe handling equipment.

13. The mobile rig of claim 7, wherein the enclosure comprises an inlet and an outlet, wherein at least one of the inlet and the outlet has a non-horizontal orientation.

14. The mobile rig of claim 7, wherein the overall sound output of the rig is not more than 80 dB.

15. The mobile rig of claim 7, further comprising a cooling system for cooling one or more sound producing equipment in the enclosure.

16. The mobile rig of claim 15, wherein the cooling system comprises an air cooling system having a fan operated by a variable frequency drive.

17. A method of reducing sound on a rig having a sound producing equipment, comprising:
at least partially enclosing the sound producing equipment in an enclosure, wherein the enclosure includes a sound absorbing material provided on a surface of the enclosure.

18. The method of claim 17, wherein the sound absorbing material comprises a foam material.

19. The method of claim 17, further comprising connecting the sound producing equipment to an electric source located remotely from the rig.

20. The method of claim 17, further comprising replacing the sound producing equipment on the rig with an electric powered equipment.
